(19) United States
(12) Patent Application Publication
(10) Pub. No.: US 2014/0175287 A1
(43) Pub. Date: Jun. 26, 2014

(54) Optical Antenna Enhanced Infrared Detector

(71) Applicant: Jarrod Vaillancourt, Rindge, NH (US)

(72) Inventor: Jarrod Vaillancourt, Rindge, NH (US)

(21) Appl. No.: 14/138,410

(22) Filed: Dec. 23, 2013

Related U.S. Application Data
(60) Provisional application No. 61/745,262, filed on Dec. 21, 2012.

(51) Int. Cl. H01L 31/0352; H01L 31/0304

(52) U.S. Cl. CPC H01L 31/035218; H01L 31/03046
USPC 250/338.4; 257/14

(57) ABSTRACT

Methods and systems for electromagnetic detection are disclosed, including providing an optical antenna enhanced detector comprising: a micro photodetector, wherein the micro photodetector comprises: a substrate; a bottom contacting layer atop the substrate; one or more active regions atop the bottom contacting layer; and a top contacting layer atop the one or more active regions; and an optical antenna integrated with the micro photodetector, wherein the optical antenna is configured to concentrate incident electromagnetic waves onto the micro photodetector; and exposing the optical antenna enhanced detector to electromagnetic waves. Other embodiments are described and claimed.

### II. CROSS REFERENCE TO RELATED APPLICATIONS

This application claims the benefit of the filing date of U.S. Provisional Patent Application Ser. No. 61/745,262, filed on Dec. 21, 2012, entitled “Optical Antenna Enhanced Infrared Detector,” the entire disclosure of which is hereby incorporated by reference into the present disclosure.

### I. STATEMENT REGARDING FEDERALLY SPONSORED RESEARCH

This invention was made with government support under contract NNX12CG15P awarded by NASA. The government has certain rights in the invention.

### III. BACKGROUND

The invention relates generally to the field of high resolution photodetection beyond the diffraction limit. More particularly, the invention relates to an optical antenna to enhance the photocurrent of middlewave and longwave infrared detectors.

### IV. SUMMARY

In one respect, disclosed is an optical antenna enhanced detector comprising: a micro photodetector, wherein the micro photodetector comprises: a substrate; a bottom contacting layer atop the substrate; one or more active regions atop the bottom contacting layer; and a top contacting layer atop the one or more active regions; a first electrode in electrical continuity with the top contacting layer; and a second electrode in electrical continuity with the bottom contacting layer; wherein at least one of the one or more active regions comprises: an InAs floating layer; a first In_{0.15}Ga_{0.85}As well atop the InAs floating layer; an InAs wetting layer atop the first In_{0.15}Ga_{0.85}As well; an InAs QD layer atop the InAs wetting layer; a second In_{0.15}Ga_{0.85}As well atop the InAs QD layer; a first GaAs spacer atop the second In_{0.15}Ga_{0.85}As well; an Al_{0.10}Ga_{0.90}As barrier atop the first GaAs spacer; and a second GaAs spacer atop the Al_{0.10}Ga_{0.90}As barrier layer; wherein the bottom contacting layer comprises: a first GaAs buffer; an n⁺ GaAs contacting layer atop the first GaAs buffer; and a second GaAs buffer atop the n⁺ GaAs contacting layer; wherein the top contacting layer comprises: a GaAs buffer; and an n GaAs contacting layer atop the GaAs buffer; wherein the substrate comprises GaAs; and an optical antenna integrated with the micro photodetector, wherein the optical antenna is configured to concentrate incident electromagnetic waves onto the micro photodetector.

In another respect, disclosed is an optical antenna enhanced detector array comprising: an array of micro photodetectors; wherein the micro photodetector comprises: a substrate; a bottom contacting layer atop the substrate; one or more active regions atop the bottom contacting layer; and a top contacting layer atop the one or more active regions; a first electrode in electrical continuity with the top contacting layer; and a second electrode in electrical continuity with the bottom contacting layer; wherein at least one of the one or more active regions comprises: an InAs floating layer; a first In_{0.15}Ga_{0.85}As well atop the InAs floating layer; an InAs wetting layer atop the first In_{0.15}Ga_{0.85}As well; an InAs QD layer atop the InAs wetting layer; a second In_{0.15}Ga_{0.85}As well atop the InAs QD layer; a first GaAs spacer atop the second In_{0.15}Ga_{0.85}As well; an Al_{0.10}Ga_{0.90}As barrier atop the first GaAs spacer; and a second GaAs spacer atop the Al_{0.10}Ga_{0.90}As barrier layer; wherein the bottom contacting layer comprises: a first GaAs buffer; an n GaAs contacting layer atop the first GaAs buffer; and a second GaAs buffer atop the n GaAs contacting layer; wherein the top contacting layer comprises: a GaAs buffer; and an n GaAs contacting layer atop the GaAs buffer; wherein the substrate comprises GaAs; and an optical antenna integrated with the at least one micro photodetector of the array of micro photodetectors, wherein the optical antenna is configured to concentrate incident electromagnetic waves onto the at least one micro photodetector.

In another respect, disclosed is a method of electromagnetic detection comprising: providing an optical antenna enhanced detector comprising: a micro photodetector; wherein the micro photodetector comprises: a substrate; a bottom contacting layer atop the substrate; one or more active regions atop the bottom contacting layer; and a top contacting layer atop the one or more active regions; a first electrode in electrical continuity with the top contacting layer; and a second electrode in electrical continuity with the bottom contacting layer; and an optical antenna integrated with the micro photodetector, wherein the optical antenna is configured to concentrate incident electromagnetic waves onto the micro photodetector; and exposing the optical antenna enhanced detector to electromagnetic waves.

Numerous additional embodiments are also possible.

### V. BRIEF DESCRIPTION OF THE DRAWINGS

Other objects and advantages of the invention may become apparent upon reading the detailed description and upon reference to the accompanying drawings.

FIG. 1 is a cross-sectional schematic diagram illustrating a quantum dot infrared photodetector utilized with an optical antenna, in accordance with some embodiments.

FIG. 2 is a top-view optical microscope picture of a micro photodetector with an integrated bowtie optical antenna, in accordance with some embodiments.

FIGS. 3A and 3B show the photocurrent spectrum of a 250 μm diameter quantum dot infrared photodetector at bias voltages of −1.0 V and −3.0 V, respectively, in accordance with some embodiments.

FIG. 4 illustrates the photocurrent versus bias voltage of a bowtie optical antenna enhanced micro QDIP compared with a non-enhanced micro QDIP, in accordance with some embodiments.

FIGS. 5A through 5F illustrate the focusing effect at different wavelengths for y-polarization light and x-polarization light, in accordance with some embodiments.

FIG. 6 is a schematic illustration of an array of bowtie optical antenna enhanced micro QDIPS, in accordance with some embodiments.

FIG. 7 is a block diagram illustrating a method for enhanced infrared photodetection beyond the diffraction limit, in accordance with some embodiments.

While the invention is subject to various modifications and alternative forms, specific embodiments thereof are shown by way of example in the drawings and the accompanying detailed description. It should be understood, however, that the drawings and detailed description are not intended to limit the invention to the particular embodiments. This disclosure is instead intended to cover all modifications, equivalents, and alternatives falling within the scope of the present invention as defined by the appended claims.

### VI. DETAILED DESCRIPTION

One or more embodiments of the invention are described below. It should be noted that these and any other embodiments are exemplary and are intended to be illustrative of the invention rather than limiting. While the invention is widely applicable to different types of systems, it is impossible to include all of the possible embodiments and contexts of the invention in this disclosure. Upon reading this disclosure, many alternative embodiments of the present invention will be apparent to persons of ordinary skill in the art.

Antennas are key components for receiving and transmitting electromagnetic waves in the RF, microwave, and millimeter spectrum regimes. Antennas can collect a large-area of free-propagating electromagnetic radiation in the RF, microwave, and millimeter spectrum regimes and convert them to localized electric current. Conversely, antennas can also radiate electromagnetic waves into free-space. Antenna technology significantly enhances the transmission efficiency and receiving sensitivity of electromagnetic waves, and allows electromagnetic waves to be emitted and received with specific radiation patterns and directions. With the advances in nanofabrication technologies, antennas in the optical regimes (optical antenna) have become a hot topic of research in both fundamental physics and device engineering applications, including photodetection, light emission, radiation pattern control, and biosensing. By properly designing the optical antenna structures, it is possible to control the optical field distribution at the nanometer scale. Such optical antenna based field manipulation enables the collection and concentration of a large area of free-propagating incident optical energy to a small region for photodetection. The strong subwavelength light collection and concentration effect can significantly increase the light intensity and thus strongly enhance light absorption for photodetection. In addition, the strong light concentration effect would also allow the reduction of the area of a photodetector, thus substantially reducing the dark current level of the photodetector. The combination of the small detection area with enhanced light absorption enables high resolution photodetection beyond the diffraction limit.

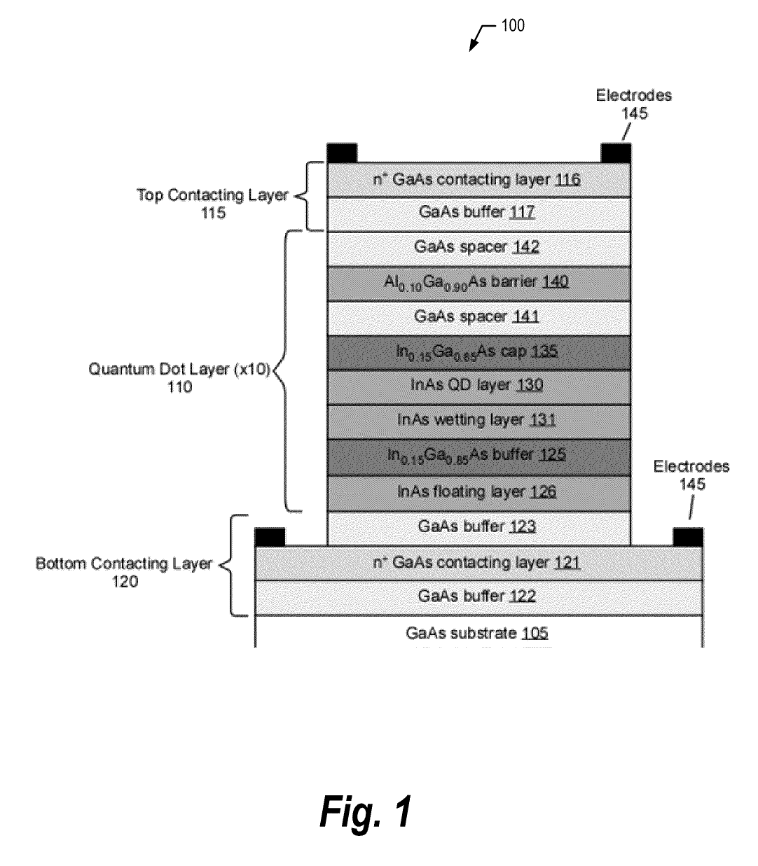

FIG. 1 is a cross-sectional schematic diagram illustrating a quantum dot infrared photodetector utilized with an optical antenna, in accordance with some embodiments.

In some embodiments, an optical antenna is integrated with a micro-photodetector such as a quantum dot infrared photodetector (QDIP) 100. The QDIP in this embodiment, grown atop a GaAs substrate 105 in a V80H molecular beam epitaxy system, comprises ten layers of vertically stacked quantum dot (QD) layers 110 sandwiched between a top n⁺ GaAs contacting layer 115 and a bottom n⁺ GaAs contacting layer 120. Each QD layer comprises a 1 nm In_{0.15}Ga_{0.85}As bottom buffer layer 125 atop a 0.72 monolayer (ML) InAs floating layer 126, a 0.6 ML InAs QD layer 130 atop a 0.69 ML InAs wetting layer 131, a 6 nm In_{0.15}Ga_{0.85}As cap layer 135, and a 2 nm Al_{0.10}Ga_{0.90}As dark current blocking barrier layer 140 sandwiched between a 60 Å bottom GaAs spacer layer 141 and a 450 Å top GaAs spacer layer 142. The top contacting layer 115 comprises a 100 nm n⁺ GaAs contacting layer 116 atop a 150 nm GaAs buffer layer 117. The bottom contacting layer 120 comprises a 300 nm n⁺ GaAs contacting layer 121 sandwiched between a 300 nm bottom GaAs buffer layer 122 and a 100 nm top GaAs buffer layer 123. Electrodes 145 are used to make electrical connections to the QDIP. Other concentration ratios for AlGaAs and InGaAs are possible, for the barrier layer and well layers, respectively.

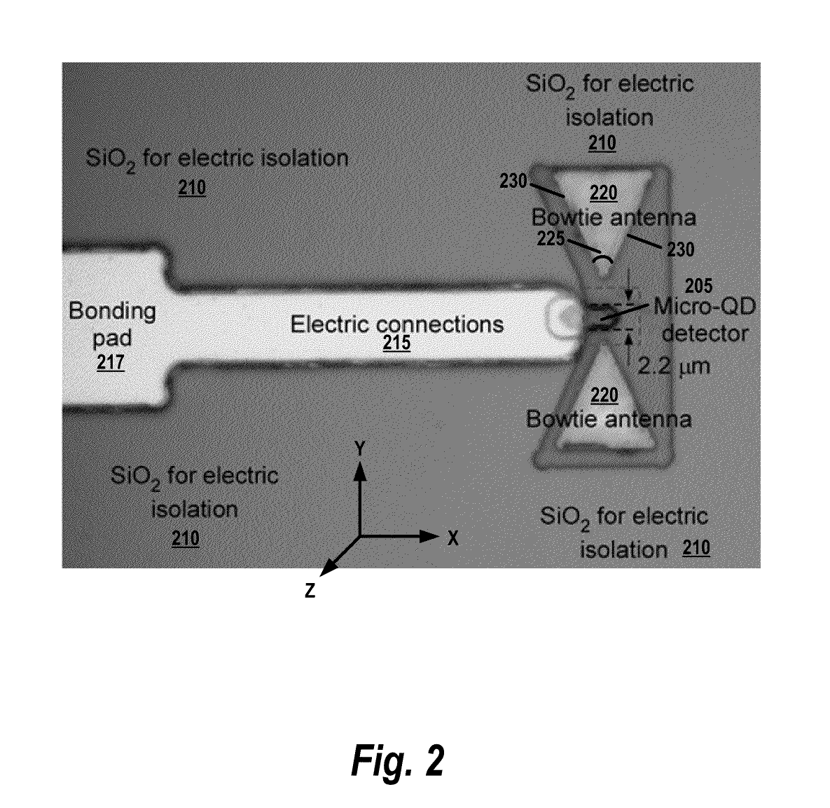

FIG. 2 is a top-view optical microscope picture of a micro photodetector with an integrated bowtie optical antenna, in accordance with some embodiments.

After the layers for the QDIP have been grown, the layers are processed into micro photodetectors using standard photolithography and wet-etching techniques. In this embodiment the micro photodetector 205 has an x-y dimension of 4 μm×2.2 μm. Next, a 400-nm thick silicon dioxide passivation layer 210 is deposited using a plasma-enhanced chemical vapor deposition process. Electrode connections 215 from the bonding pad 217 to the micro QDIP comprise bottom and top N-type (Ni(50 Å)/Ge(170 Å)/Au(330 Å)/Ni(150 Å)/Au(3000 Å)) alloys fabricated by the standard E-beam metal evaporation deposition, lift-off, and thermal annealing processes. Finally, a 30 nm thick gold (Au) optical antenna 220 is deposited to surround each micro photodetector and to be aligned vertically within the active region of the QDIP, i.e. the quantum dot layer 110. Any optical antenna design, such as a dipole optical antenna, a Yagi-Uda antenna, other type of optical antenna, and their complementary patterns that concentrates the incident electromagnetic radiation onto the photodetector is possible, but in this embodiment, a bowtie shaped optical antenna is utilized. The triangular electrodes of the bowtie antenna have an inner angle 225 of 49.6 degrees with side arm lengths 230 of 16.5226 microns at the vertex closest to the QDIP. In this embodiment, the tips of the Au bowtie antenna are separated by roughly 5 microns. The QDIP in this embodiment is for the detection of longwave infrared, but the bowtie optical antenna enhancement may also be used with other micro optical detectors at other wavelength sensitivities such as middlewave infrared.

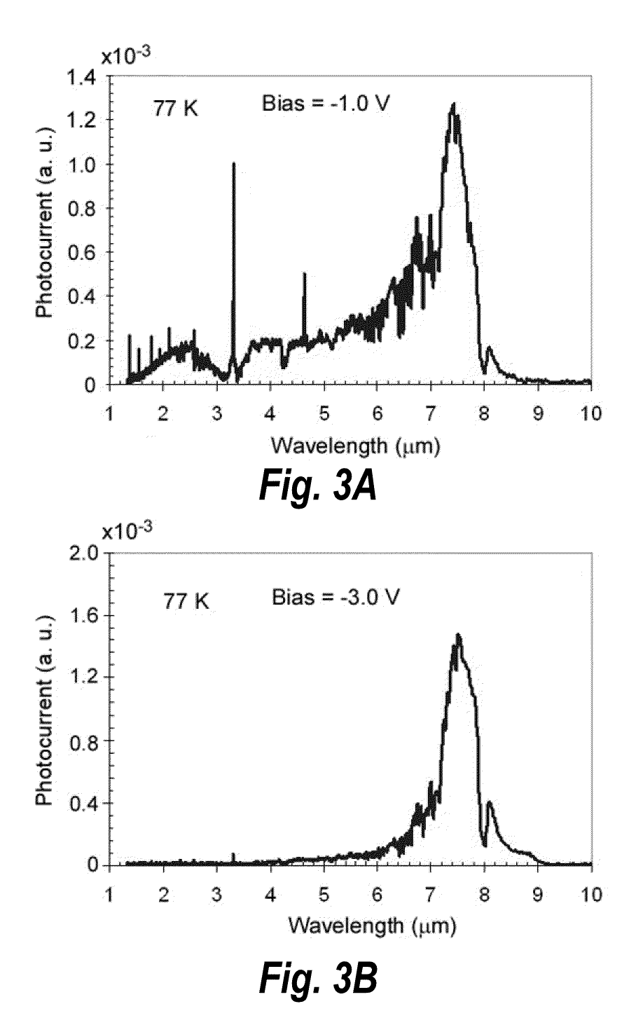

FIGS. 3A and 3B show the photocurrent spectrum of a 250 μm diameter quantum dot infrared photodetector at bias voltages of −1.0 V and −3.0 V, respectively, in accordance with some embodiments.

The photocurrent spectra at 77 K of a 250 μm diameter QDIP having the same vertical structure as the micro-photodetector of FIG. 1 are shown in FIGS. 3A and 3B. The 250 μm diameter QDIP, minus the optical antenna, is used as a reference to examine the bias-dependent photoresponse of the QDIP structure of FIG. 1. FIG. 3A shows that the photocurrent spectrum at the bias voltage of −1.0 V covers a broad spectrum range from about 1.6 μm to about 8.6 μm; whereas FIG. 3B shows that the photocurrent spectrum at the bias voltage of −3.0 V covers a narrower spectrum range from about 6.2 μm to about 9.0 μm.

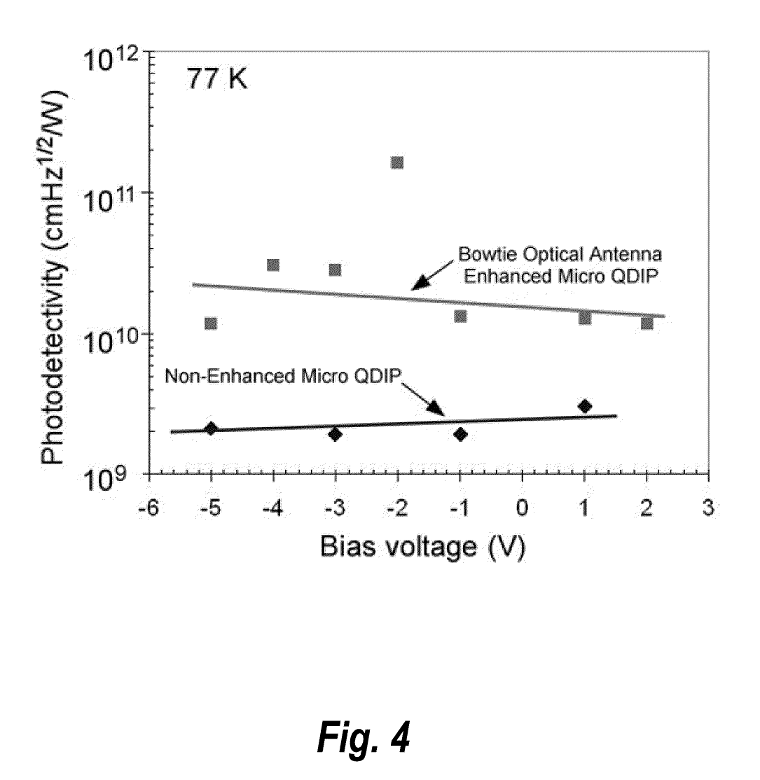

FIG. 4 illustrates the photocurrent versus bias voltage of a bowtie optical antenna enhanced micro QDIP compared with a non-enhanced micro QDIP, in accordance with some embodiments.

The square data points represent measured data for the bowtie optical antenna enhanced micro QDIP. The solid line between the square data points is a linear curve fit between the square data points for the bowtie optical antenna enhanced micro QDIP. The diamond data points represent measured data for the non-enhanced micro QDIP. The solid line between the diamond data points is a linear curve fit between the diamond data points for the non-enhanced micro QDIP. Overall, the bowtie optical antenna enhanced micro QDIP shows a roughly ten times enhancement in the photocurrent over the non-enhanced micro QDIP. Photocurrents of over 10⁻¹² (A) are obtained for all the bias voltages of FIG. 4 for the bowtie optical antenna enhanced micro QDIP. In contrast, the photocurrents for the non-enhanced micro QDIP are all less than 10⁻¹² (A) for all the bias voltages of FIG. 4. As the bias increases, the photocurrent enhancement between the bowtie optical antenna enhanced micro QDIP and the non-enhanced micro QDIP becomes less as a result of the bias dependent photoresponse as shown in FIGS. 3A and 3B. The higher photocurrent enhancement at the larger negative bias shows that the bowtie optical antenna enhanced micro QDIP is more efficient in collecting longer wavelength IR light.

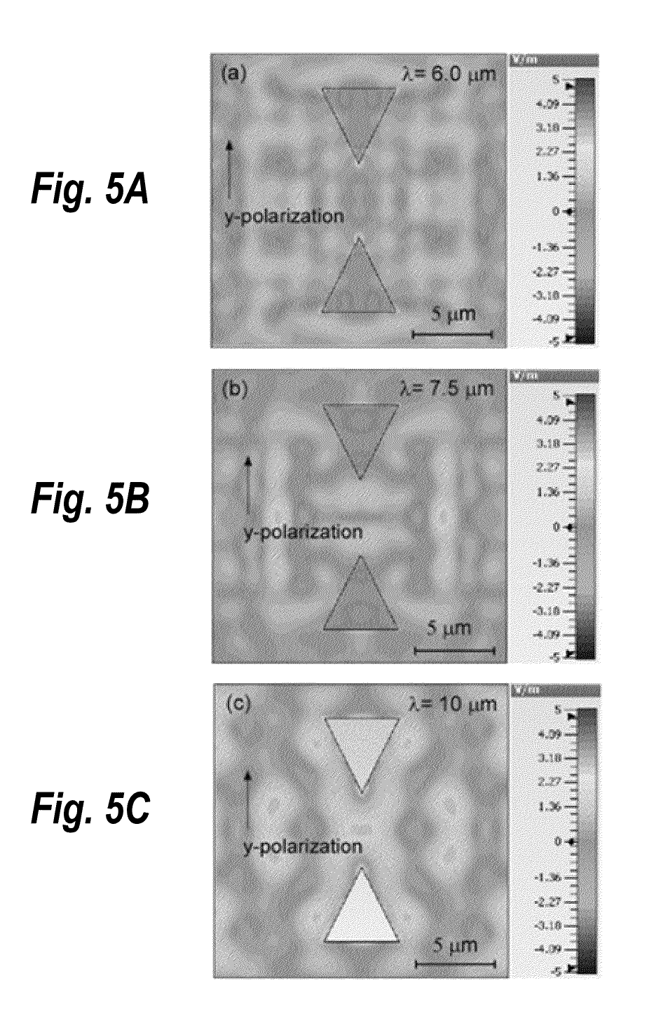

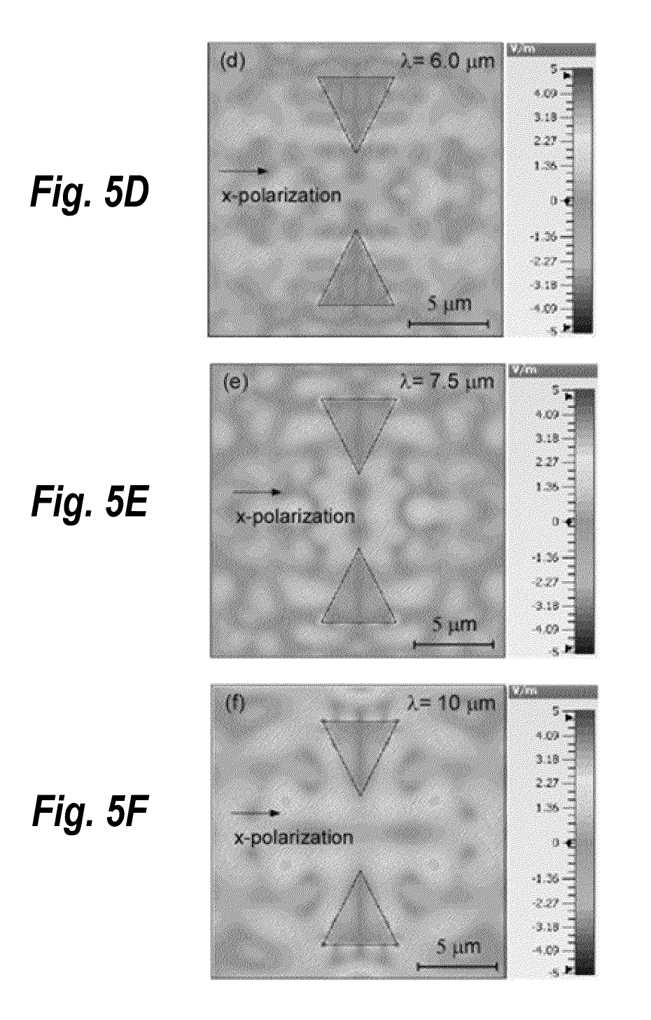

FIGS. 5A through 5F illustrate the focusing effect at different wavelengths for y-polarization light and x-polarization light, in accordance with some embodiments.

CST Microwave Studio was used to simulate the electric field distribution of the bowtie optical antenna enhanced micro QDIP. FIGS. 5A, 5B, and 5C show the electric field distribution of the y-polarized light for the wavelengths of 6.0 μm, 7.5 μm, and 10.0 μm, respectively. As can be observed in FIG. 5C, at longer wavelengths, the bowtie optical antenna shows a higher electric field concentration in the area between the tips of the electrodes of the bowtie optical antenna. FIGS. 5D, 5E, and 5F show the electric field distribution of the x-polarized light for the wavelengths of 6.0 μm, 7.5 μm, and 10.0 μm, respectively. The x-polarization also exhibits a higher electric field concentration in the area between the tips of the electrodes of the bowtie optical antenna.

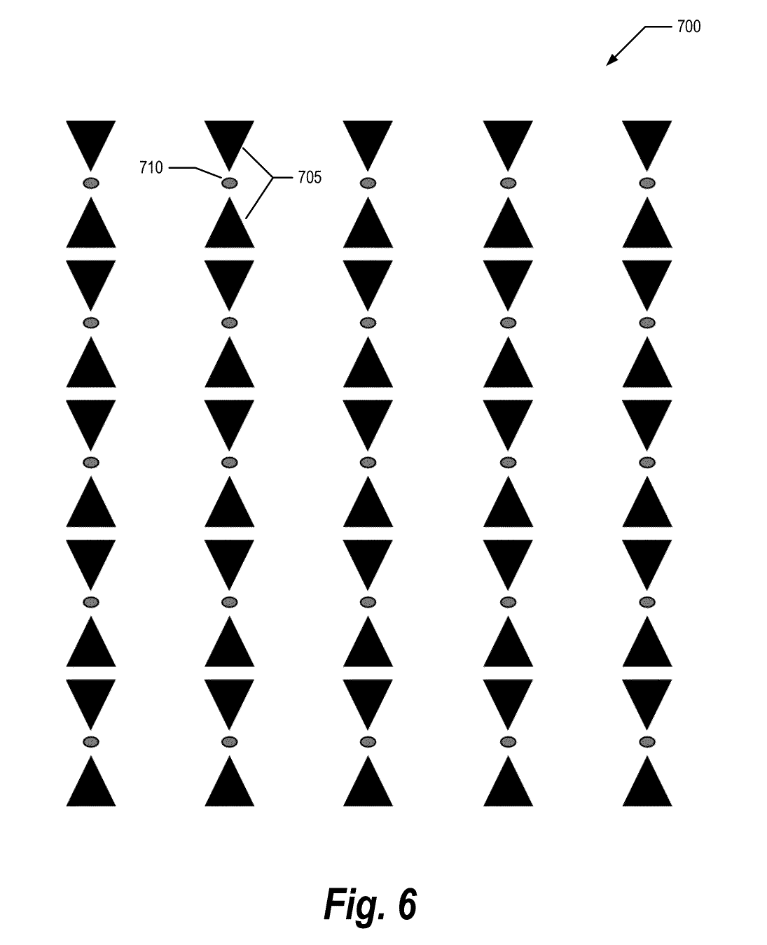

FIG. 6 is a schematic illustration of an array of bowtie optical antenna enhanced micro QDIPS, in accordance with some embodiments.

In some embodiments, an array of QDIPs comprises bowtie optical antenna enhanced micro QDIPs. The high photodetectivity combined with the small detection area of a few square microns of each of the bowtie optical antenna enhanced micro QDIPs provides for high performance IR sensing with high resolution beyond the diffraction limit. In the embodiment schematically illustrated in FIG. 6, the array of QDIPs comprises twenty-five bowtie optical antenna enhanced micro QDIPS. Each micro QDIP 710 is integrated with a bowtie optical antenna 705. The electrical interconnections are omitted for clarity. The bowtie optical antenna enhancement may also be used with other micro optical detectors as well as with other array sizes. Additionally, any optical antenna design that concentrates the incident electromagnetic radiation onto each of the photodetectors is possible, but in this embodiment, a bowtie shaped optical antenna is utilized. It is also possible to utilize multiple optical antenna designs with different optical detectors within the same detector array.

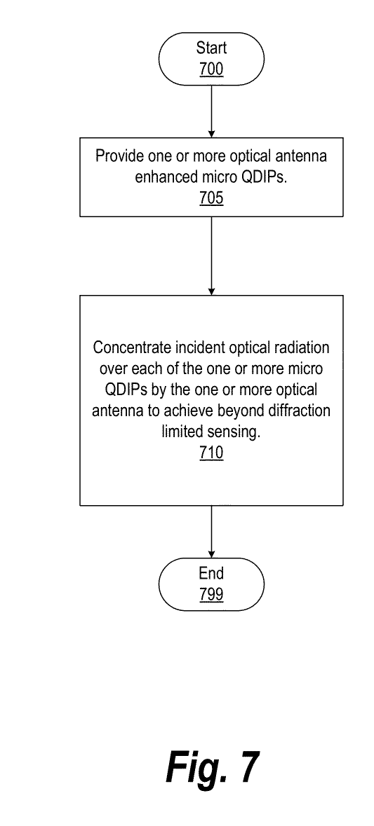

FIG. 7 is a block diagram illustrating a method for enhanced infrared photodetection beyond the diffraction limit, in accordance with some embodiments.

In some embodiments, the method illustrated in FIG. 7 may be performed by one or more of the devices illustrated in FIG. 1, FIG. 2, and FIG. 6. Processing begins at 700 whereupon, at block 705, one or more optical antenna enhanced micro QDIPs is provided. At block 710, incident optical radiation is concentrated over each of the one or more micro QDIPs by the one or more optical antenna to achieve beyond diffraction limited sensing. Processing subsequently ends at 799.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

The benefits and advantages that may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

While the present invention has been described with reference to particular embodiments, it should be understood that the embodiments are illustrative and that the scope of the invention is not limited to these embodiments. Many variations, modifications, additions, and improvements to the embodiments described above are possible. It is contemplated that these variations, modifications, additions, and improvements fall within the scope of the invention as detailed within the following claims.

1. An optical antenna enhanced detector comprising:
a micro photodetector, wherein the micro photodetector comprises:
a substrate;
a bottom contacting layer atop the substrate;
one or more active regions atop the bottom contacting layer; and
a top contacting layer atop the one or more active regions; and
an optical antenna integrated with the micro photodetector, wherein the optical antenna is configured to concentrate incident electromagnetic waves onto the micro photodetector.

2. The optical detector of claim 1, wherein the micro photodetector comprises a quantum dot infrared photodetector.

3. The optical antenna enhanced detector of claim 1, wherein the micro photodetector further comprises:
a first electrode in electrical continuity with the top contacting layer; and
a second electrode in electrical continuity with the bottom contacting layer.

4. The optical antenna enhanced detector of claim 1, wherein at least one of the one or more active regions comprises:
a floating layer;
a first well atop the floating layer;
a wetting layer atop the first well;
a QD layer atop a wetting layer;
a second well atop the QD layer;
a first spacer atop the second well;
a barrier layer atop the first spacer; and
a second spacer atop the barrier layer.

5. The optical antenna enhanced detector of claim 4, wherein:
the floating layer comprises InAs;
the first well comprises In_{0.15}Ga_{0.85}As;
the wetting layer comprises InAs;
the QD layer comprises InAs;
the second well comprises In_{0.15}Ga_{0.85}As;
the first spacer comprises GaAs;
the barrier layer comprises Al_{0.10}Ga_{0.90}As; and
the second spacer comprises GaAs.

6. The optical antenna enhanced detector of claim 1, wherein the bottom contacting layer comprises:
a first GaAs buffer;
an n⁺ GaAs contacting layer atop the first GaAs buffer; and
a second GaAs buffer atop the n⁺ GaAs contacting layer.

7. The optical antenna enhanced detector of claim 1, wherein the top contacting layer comprises:
a GaAs buffer; and
an n⁺ GaAs contacting layer atop the GaAs buffer.

8. The optical antenna enhanced detector of claim 1, wherein the substrate comprises GaAs.

9. The optical antenna enhanced detector of claim 1, wherein the optical antenna comprises at least one of: a bowtie optical antenna, a dipole optical antenna, a Yagi-Uda antenna, a complementary bowtie optical antenna, a complimentary dipole optical antenna, and a complimentary Yagi-Uda antenna.

10. The optical antenna enhanced detector of claim 1, wherein the micro photodetector detects electromagnetic waves beyond the diffraction limit.

11. The optical antenna enhanced detector of claim 1, wherein the micro photodetector detects electromagnetic waves ranging from about 8 microns to about 14 microns.

12. The optical antenna enhanced detector of claim 1, wherein the micro photodetector detects electromagnetic waves ranging from about 3 microns to about 8 microns.

13. An optical antenna enhanced detector array comprising:
an array of micro photodetectors, wherein at least one micro photodetector of the array of micro photodetectors comprises:
a substrate;
a bottom contacting layer atop the substrate;
one or more active regions atop the bottom contacting layer; and
a top contacting layer atop the one or more active regions;
electrical interconnections to the array of micro photo detectors; and
an optical antenna integrated with the at least one micro photodetector of the array of micro photo detectors, wherein the optical antenna is configured to concentrate incident electromagnetic waves onto the at least one micro photodetector.

14. The optical antenna enhanced detector array of claim 13, wherein the at least one micro photodetector comprises a quantum dot infrared photodetector.

15. The optical antenna enhanced detector array of claim 13, wherein the at least one micro photodetector further comprises:
a first electrode in electrical continuity with the top contacting layer; and
a second electrode in electrical continuity with the bottom contacting layer.

16. The optical antenna enhanced detector array of claim 13, wherein at least one of the one or more active regions comprises:
a floating layer;
a first well atop the floating layer;
a wetting layer atop the first well;
a QD layer atop a wetting layer;
a second well atop the QD layer;
a first spacer atop the second well;
a barrier layer atop the first spacer; and
a second spacer atop the barrier layer.

17. The optical antenna enhanced detector array of claim 16, wherein:
the floating layer comprises InAs;
the first well comprises In_{0.15}Ga_{0.85}As;
the wetting layer comprises InAs;
the QD layer comprises InAs;
the second well comprises In_{0.15}Ga_{0.85}As;
the first spacer comprises GaAs;
the barrier layer comprises Al_{0.10}Ga_{0.90}As; and
the second spacer comprises GaAs.

18. The optical antenna enhanced detector array of claim 13, wherein the bottom contacting layer comprises:
a first GaAs buffer;
an n⁺ GaAs contacting layer atop the first GaAs buffer; and
a second GaAs buffer atop the n⁺ GaAs contacting layer.

19. The optical antenna enhanced detector array of claim 13, wherein the top contacting layer comprises:
a GaAs buffer; and
an n⁺ GaAs contacting layer atop the GaAs buffer.

20. The optical antenna enhanced detector array of claim 13, wherein the substrate comprises GaAs.

21. The optical antenna enhanced detector array of claim 13, wherein the optical antenna comprises a bowtie optical antenna.

22. The optical antenna enhanced detector array of claim 13, wherein the micro photodetector detects electromagnetic waves beyond the diffraction limit.

23. The optical antenna enhanced detector array of claim 13, wherein the micro photodetector detects electromagnetic waves ranging from about 8 microns to about 14 microns.

24. The optical antenna enhanced detector array of claim 13, wherein the micro photodetector detects electromagnetic waves ranging from about 3 microns to about 5 microns.

25. A method of electromagnetic detection comprising:
providing an optical antenna enhanced detector comprising:
a micro photodetector, wherein the micro photodetector comprises:
a substrate;
a bottom contacting layer atop the substrate;
one or more active regions atop the bottom contacting layer; and
a top contacting layer atop the one or more active regions; and;
an optical antenna integrated with the micro photodetector, wherein the optical antenna is configured to concentrate incident electromagnetic waves onto the micro photodetector; and
exposing the optical antenna enhanced detector to electromagnetic waves.

26. The method of claim 25, wherein at least one of the one or more active regions comprises:
a floating layer;
a first well atop the floating layer;
a wetting layer atop the first well;
a QD layer atop a wetting layer;
a second well atop the QD layer;
a first spacer atop the second well;
a barrier layer atop the first spacer; and
a second spacer atop the barrier layer.

27. The method of claim 25, wherein:
the floating layer comprises InAs;
the first well comprises In_{0.15}Ga_{0.85}As;
the wetting layer comprises InAs;
the QD layer comprises InAs;
the second well comprises In_{0.15}Ga_{0.85}As;
the first spacer comprises GaAs;
the barrier layer comprises Al_{0.10}Ga_{0.90}As; and
the second spacer comprises GaAs.

28. The method of claim 25, wherein the bottom contacting layer comprises:
a first GaAs buffer;
an n⁺ GaAs contacting layer atop the first GaAs buffer; and
a second GaAs buffer atop the n⁺ GaAs contacting layer.

29. The method of claim 25, wherein the top contacting layer comprises:
a GaAs buffer; and
an n⁺ GaAs contacting layer atop the GaAs buffer.

30. The method of claim 25, wherein the substrate comprises GaAs.

31. The method of claim 25, wherein the micro photodetector further comprises:
a first electrode in electrical continuity with the top contacting layer; and
a second electrode in electrical continuity with the bottom contacting layer.
